(19) United States
(12) Patent Application Publication
(10) Pub. No.: US 2009/0032926 A1
(43) Pub. Date: Feb. 5, 2009

(54) Integrated Support Structure for Stacked Semiconductors With Overhang

(75) Inventor: Reza Sharifi, Palatine, IL (US)

Correspondence Address: ADVANCED MICRO DEVICES, INC.;C/O VEDDER PRICE P.C., 222 N.LASALLE STREET, CHICAGO, IL, 60601, US

(73) Assignee: Advanced Micro Devices, Inc., Sunnyvale, CA (US)

(21) Appl. No.: 11/831,392

(22) Filed: Jul. 31, 2007

(51) Int. Cl. H01L 23/02; H01L 21/00

(52) U.S. Cl. 257/686; 438/109; 257/E23.173; 257/E21.705

(57) ABSTRACT

The present disclosure relates to an integrated circuit packaging, a strip having a plurality of integrated circuit packages, and method of manufacture thereof, and more particularly, to a substrate having an integrated overhang support structure to support a ledge created by stacking a large circuit die on a small circuit die. In one embodiment, the upper substrate surface comprises a protrusion as an integrated support structure. The structure may include passages to direct the flow of underfill into the limited support area to create an open area for vacuum or for placement of passive or active components.

### FIELD OF THE INVENTION

The present invention relates to an integrated circuit package, a strip having a plurality of integrated circuit packages, a device having an integrated circuit package, and a method of fabrication thereof.

### BACKGROUND OF THE INVENTION

Most electronics rely on integrated circuit technology that includes a substrate of semiconductor material made of electronic elements and electronic circuits referred to as a chip or die. Chips are electrically connected to other electronic elements or components via electric conductors at a conductive pad interface on the outer surface of chips. Wire bonding, a technique where small wires are used to connect two distant points, is used to connect pads of chips to connectors of neighboring elements or other chips. A needle-like capillary machine, often called a wire-bonding machine, deposits a thin, high-voltage wire onto a pad where the tip of the wire is melted and forms a spherical weld on the pad. Once the first weld is cooled, the capillary machine moves to the destination end of the wire to attach and weld the destination end in a similar fashion. Wire-bonding machines are highly automated and can repeat this operation multiple times per second on a single chip, often resulting in repeated local strain on the surface of delicate chips. Since chip pads are often located on the external edge, the strain is often directed to the outer edge of the chip and may result in damage of the external edge.

Wire-bonding machines often bond circuit chips to substrates on which the circuit chip is secured. Another method of bonding chips to a substrate is arranging pads in the form of an array on a single side of the chip rather than arranging these pads along the outer edges of the circuit chip. Each pad in the array is then covered by a rounded solder ball, which is a liquid structure forming a ball based on surface tension properties of the solder material. Chips mounted with solder balls are generally referred to as “Flip-Chips,” “Wafer Level Packages (WLP),” or “Flip-Chip Dies” because they are mounted upside-down on a substrate. Solder balls or bumps are larger than normal wires or pins, and this added matter results in an improved electrical connection between the chip and the substrate. These solder ball connectors provide additional thermal conduction between the printed circuit board or substrate and the chip. Flip-chip technology results in the creation of a complex geometry located between the different connectors between the chip and the substrate. A liquid encapsulant called “underfill” is often inserted in the area between the flip-chip connectors once the chip is flipped onto a substrate.

The demand for low-cost, high-performance miniaturization and greater density of electronic packages in the art is well known. One approach is to place dies on top of each other in a stacked configuration. Stacking allows for greater density of wire bonds, better heat conductivity, and the need of less molding compound to protect the resulting package. Pyramidal stacking of circuit dies of increasingly small sizes provides access to the external edge of each successive circuit die for wire bonding. But stacking creates connection problems when the upper chip stacked above an under chip is equal or larger in size than the chip on which the upper chip must rest. Another approach is to stack a bottom flip-chip free of wire bonding under a top circuit die having wire bonds. However, this stacking configuration has numerous drawbacks.

FIGS. 1 and 2 of the prior art show a flip-chip as a first circuit die capable of supporting on its upper surface a second circuit die attached by wire bonds to either the substrate or the flip-chip itself (as shown). The upper circuit die to be secured must be of smaller surface area than the bottom circuit die to allow for placement of wire bonds pads along the edges of the bottom chip. FIG. 3 of the prior art shows the use of a spacer to provide clearance between successively stacked dies to protect wire bonds. The use of spacers defeats the objective of stacking of dies to obtain a compact configuration. FIG. 4 of the prior art shows a configuration where two upper dies placed on a flip-chip are bonded to a substrate. Access to the top surface of the intermediate die is made possible by the use of a spacer. FIG. 5 of the prior art shows a configuration where the top circuit die is larger and placed on a smaller, inferior circuit die, which results in the creation of a overhang between the dies. Further, FIG. 5 shows a solution as described hereafter to remedy to the overhang problem. A capillary machine attaching wire bonds on the upper surface of the larger die induces vertical strain on the large die at the junction of the overhang. Cracking and chipping of dies has been observed as a result of this process. One solution is to use gentler capillary machines capable of wire bonding without creation of vertical strain on a circuit die.

Another method is to fill in the volume located under the overhang with a liquid epoxy resin or other dielectric molding compound after the upper die is stacked on the lower die. Once the resin has dried, the compound provides limited mechanical support to the overhang based on the rigidity of the solidified compound. These compounds, however, are also susceptible to fill part of the area and create undesired forces on the overhang depending of thermal expansion coefficients between the circuit die and the compound. Dispensed liquids also flow in to occupy the entire volume under an overhang unless constrained by a barrier.

Other techniques exist where, for example, a dielectric molding compound includes microspheres with a sphere diameter capable of reinforcing the support area of the overhang by placing rigid spheres in contact of the upper circuit die and the substrate. The use of a dual nature compound (e.g., small and large spheres) only compounds the described problems above. Large microspheres, when placed uniformly in the right locations, must still have precise radii to operate properly. If the spheres are too small, they offer no support and hinder the capacity of molding compound to occupy the volume between the sphere and the circuit chip overhang. If the spheres are too large, they are unable to be dispensed at the correct location and must be deformed and preconstrained in place, which results in residual vertical forces on the overhang structure when the spheres are in fact designed to protect these surfaces from vertical forces.

In one other embodiment of the prior art, a preformed support structure formed at a predetermined height is inserted under the overhang for support during the industrial process. This preformed support structure requires additional manipulation during the manufacturing process. The preformed support must be placed with adhesives at a precise position on the upper surface of the substrate and requires precise control of vertical tolerances between the support and overhang. In the art of mechanical support, vertical tolerances are very important. By way of an analogous illustration, if a vertical support is used to hold the overhang of a glass table having little or no vertical flexibility, it is understood that the height of the vertical support must be precisely measured and calibrated to perform its intended function. The use a support that may be too soft, too short, or too high only serves to compound structural limitations instead of alleviating them. Supports require top and bottom bonding agents and create unwanted tolerance requirements.

Accordingly, a need exists for an improved support design for the overhang of stacked dies and packages and methods relating thereto.

### BRIEF DESCRIPTION OF THE DRAWINGS

The features of the present disclosure are believed to be novel and are set forth with particularity in the appended claims. The disclosure may best be understood by reference to the following description taken in conjunction with the accompanying drawings. Figures that employ like reference numerals identify like elements.

FIG. 1 is a cross-sectional view of a two-level pyramidal integrated circuit package according to teaching of the prior art.

FIG. 2 is a cross-sectional view of a three-level pyramidal integrated circuit package according to further teaching of the prior art.

FIG. 3 is a cross-sectional view of a three-level pyramidal integrated circuit package with a spacer according to further teaching of the prior art.

FIG. 4 is a partial cross-sectional view of the integrated circuit package of FIG. 3 wire bonded to a substrate according to teaching of the prior art.

FIG. 5 is a cross-sectional view of stacked semiconductors with an overhang having a dielectric compound as a support structure located below the overhang according to teaching of the prior art.

FIG. 6 is a cross-sectional view of an integrated circuit package with an integrated support structure in the substrate according to an embodiment of the present invention.

FIG. 7 is a perspective view of the substrate with a rectangular integrated support structure as shown in FIG. 6.

FIG. 8 is a perspective view of the substrate with a rectangular integrated support structure of FIG. 7 where the support structure defines at least one passage therethrough.

FIGS. 9 is a cross-sectional view of the integrated circuit package with an integrated support structure as shown in FIG. 8 according to another embodiment of the present invention.

FIG. 10 is a perspective view of the substrate with a rectangular integrated support structure without corner portions according to another embodiment of the present invention.

FIG. 11 is a cross-sectional view of the integrated package as shown in FIG. 7 with passive components placed between the integrated support structure and the first circuit die according to another embodiment of the present invention.

FIG. 12 is a cross-sectional view of the integrated package as shown in FIG. 7 where the integrated support structure is replaced with a recess in the upper substrate surface to house the first circuit die according to another embodiment of the present invention.

FIG. 13 is a flow chart of a method according to an embodiment of the present disclosure.

FIG. 14 is a side elevation of an integrated package strip made of a plurality of integrated circuit packages as shown on FIG. 8.

FIG. 15 is a top view of the substrate of the integrated package strip of FIG. 14.

FIG. 16 is a block diagram of an exemplary device that may be used to implement the integrated circuit package in accordance with the present disclosure.

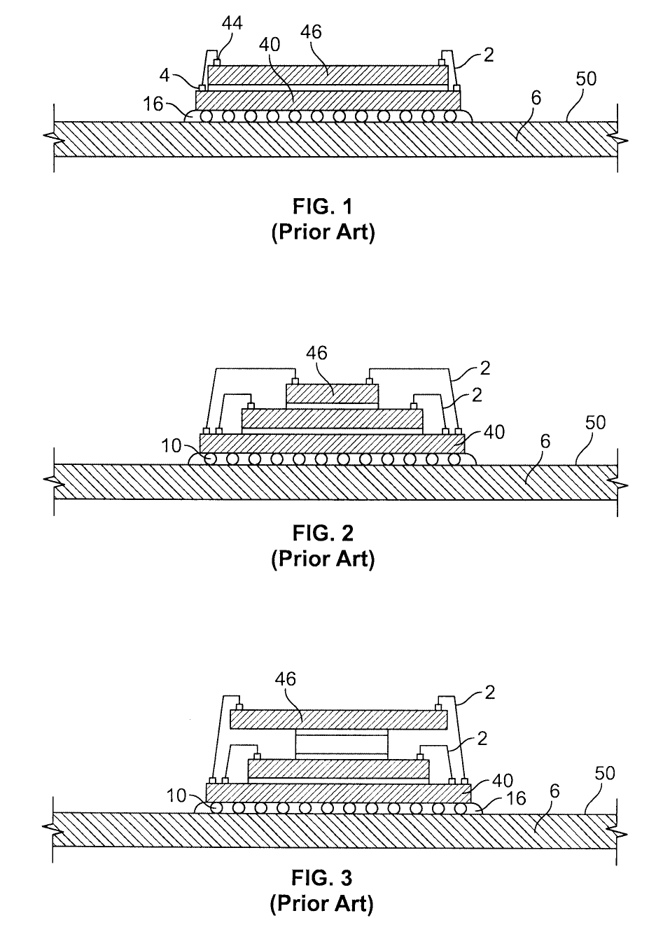

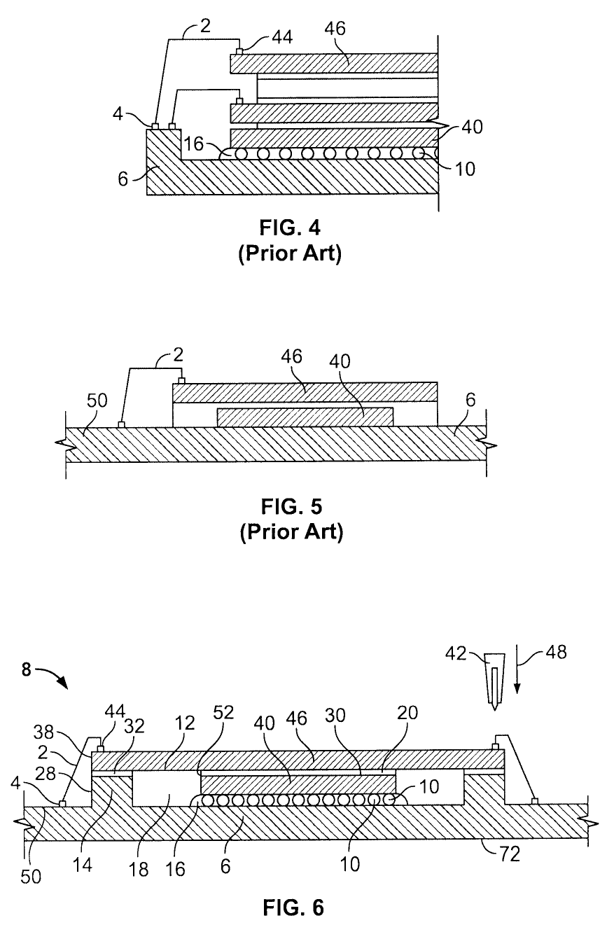

### DETAILED DESCRIPTION

In the following detailed description, reference is made to the accompanying drawings that show, by way of illustration, several embodiments of the disclosure, each being centered around an integrated support structure for stacked semiconductors with overhang, a strip having a plurality of integrated circuit packages, a device having an integrated circuit package, and a method of manufacture thereof. These embodiments are described with detail sufficient to enable one skilled in the art to practice the disclosure. It is understood that the various embodiments of the disclosure, though different, are not necessarily exclusive and can be combined differently because they show novel features. For example, a particular feature, structure, step of manufacture, or characteristic described in connection with one embodiment may be implemented within other embodiments without departing from the spirit and scope of the disclosure. In addition, it is understood that the location and arrangement of individual elements, such as geometric parameters within each disclosed embodiment, may be modified without departing from the spirit and scope of the disclosure. Other variations are also recognized by one of ordinary skill in the art. The following detailed description is, therefore, not to be taken in a limiting sense but only provides examples.

This disclosure provides an improved solution that may be implemented, with or without the use of gentler capillary machines, to protect integrated circuit packages with overhang during wire-bonding processes directed at providing support to the overhang of stacked circuit dies or to protect against damage due to vibration or other stresses after the package has been formed. The present disclosure also relates to an integrated circuit package and/or a strip having a plurality of integrated circuit packages and method of manufacture thereof, and more particularly, to a substrate having an integrated overhang support structure to support a ledge created by stacking a large circuit die on a small circuit die. It is to be understood that any suitable configuration other than the rectangular embodiments described herein could also be used. In one embodiment, the upper substrate surface includes a protrusion in the shape of a rectangular border, or a partial rectangular border, that surrounds a WLP also of rectangular geometry. In another embodiment, the support structure has passages to direct the flow of underfill to the underfill area located between solder balls of a WLP within the cavity created within the integrated support structure. In another embodiment, the integrated support structure is limited under the outer edge of the second circuit die to an outer border to create an open area between the first circuit die and the integrated support structure free of the integrated support structure. The area in one contemplated embodiment is sealed or vacuum sealed to provide an environmental control in the cavity and ward off damage to the first circuit chip due to environmental degradations. In another embodiment, passive or active components are inserted in the area between the integrated support structure and the first circuit die. In yet another embodiment, the integrated support structure is created in the substrate by a recess from the upper substrate surface to house and support a first circuit die, a second circuit die, or even passive and active components located in an area created between the integrated support structure and the first circuit die.

The present disclosure is described with respect to preferred embodiments in a specific context, namely, a semiconductor package comprising a substrate and two stacked dies, the first being a WLP and the second a wire-bonded chip. The disclosure may also apply, however, to other semiconductor devices that include more than two stacked dies, as well as to devices incorporating preferred embodiments of the disclosure on more than one level.

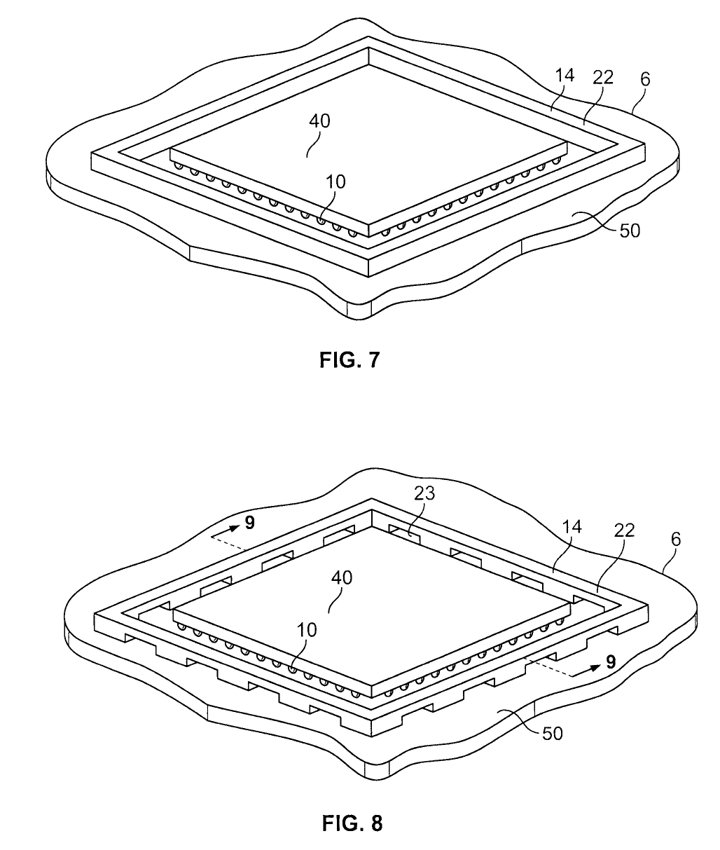

FIG. 6 is a cross-sectional view of an integrated circuit package 8 with an integrated support structure 14 in a substrate 6 according to an embodiment of the present invention. It is also shown is the head of a capillary machine 42 capable of wire bonding a wire 2 between two ends 44 and 4 located respectively on a second circuit die 46 and a substrate 6. FIG. 6 illustrates schematically next to the capillary machine head 42 a vertical force 48 created by the bonding of a wire 2 on the second circuit die 46. It is to be is understood (but not shown) that there is the creation of a strain distribution in the second circuit die 46 as a result of the vertical force 48 applied to the end 44. The integrated support structure 14 provides support immediately below or proximate a location where a vertical force 48 is applied, which creates a counter-force on the second circuit die 46 to partly annul or reduce the strain created on the second circuit die 46 by the vertical force 48.

The substrate 6 includes an upper substrate surface 50 and a lower substrate surface 72. The substrate 6 may be made of any suitable material or materials. One of the materials may be a material selected from the group of glass, metal, ceramic, polymer, silicon substrate, SOI substrate, PCB substrate, semiconductor, conductor, insulator, or SiGe substrate. It is also contemplated (but not shown) is the use of substrates 6 with laminated, multilayer, conductive bumps, pins, or traces. It is also contemplated as a substrate 6 is any type of printed wiring boards, etched wiring board, or laminate.

FIG. 6 shows that which is most commonly used in the industry, namely, a substrate 6 of a fixed thickness where the upper and lower substrate surfaces 50, 72 are in opposition. The first circuit die 40 as shown is supported by the substrate 6, and the second circuit die 46 is positioned over the first circuit die 40 to create a ledge 12 that extends over an edge 52 of the first circuit die 40. The substrate 6 includes the integrated support structure 14 positioned under the ledge 12 to support the ledge 12 of the second die 46. In one embodiment, the integrated support structure 14 is 200 to 400 microns thick. The integrated support structure 14 is integrally formed as a part of the substrate 6, as opposed, for example, to a separate piece adhesively mounted to the substrate 6.

The first circuit die 40 and a second circuit die 46 may be of different technologies. For example, the first circuit die 40 is a WLP, and the second circuit die 46 is a wire-bonded chip. The WLP as shown includes a series of connector balls 10 attached to one side of the first circuit die 40. In a possible embodiment, underfill material 16 is seeped by capillary action between the solder balls of the WLP. In a preferred embodiment, the underfill may be made of the snap cure, low-profile, high-performance, or reworkable types. It is contemplated that any commercially available material sold for underfill applications that can be used in conjunction with the present invention and any commercially available dispensing equipment may also be used to practice the invention. However, no underfill may be used if desired.

In this example, the first circuit die 40 is encased between the substrate 6, the second circuit die 46, and the integrated support structure 14 formed as a protrusion 22 of the substrate 6. Since the second circuit die 46 as shown is horizontally larger than the first circuit die 40 on which it is placed, the portion of the second circuit die 46 that is not in immediate contact above the upper surface 30 or in contact with an adhesive 20 dispensed by capillary and tape methods placed over the upper surface 30 as contemplated in alternate embodiments forms a ledge 12 (i.e., a cantilevered portion of die 46) that extends over an edge 52 of the first circuit die 40 beyond an outer edge of the protrusion 28 (although shown to be substantially flush thereto). When the ledge 12 is placed over an integrated support structure 14 having a thickness inferior to the distance between an upper surface 30 of the first circuit die 40 and the upper substrate surface 50 with an adhesive 20, the second circuit die 46 is made to rest upon the upper surface 30 or the adhesive 20 placed thereupon. If the ledge 12 is placed over an integrated support structure 14 having a thickness equal or superior to the distance between an upper surface 30 of the first circuit die 40 and the upper substrate surface 50 with an adhesive 20, then the second circuit die 46 is made to rest upon the integrated support structure 14.

As illustrated, the outer edge of the protrusion 28 is located at approximately the same distance from the edge 52 as the outer end 38 of second circuit die 46. However, this need not be the case. It is to be understood by one of ordinary skill of the need to create an integrated support structure 14 of a thickness and height sufficient to adequately support the ledge 12. FIG. 7 shows a situation where the integrated support structure 14 is a protrusion 22 of the upper substrate surface 50. The integrated support structure 14 as shown is of a thickness above the upper substrate surface 50 sufficient to encompass the first circuit die 40 and an associated layer of adhesive 20 placed between the first circuit die 40 and the second circuit die 46. While one possible thickness is shown, the use of an integrated support structure 14 of a height sufficient to house the first circuit die 40 and provide support to the ledge 12 of the second circuit die 46 is contemplated. Also shown is the use of an adhesive 32 located between the integrated support structure 14 and the ledge 12. It is also contemplated is an integrated circuit package 8 where no adhesive 20, 32 is found at the interface between the first circuit die 40 and the second circuit die 46. As for the adhesive 20, 32, It is also contemplated is the situation where other mechanical means are employed to secure the second circuit die 46 to the integrated support structure 14. The integrated support structure 14 as shown is also of a thickness and distance from the upper substrate surface 50 and the edge 52 of the first circuit die 40 sufficient for an area 18 to be created. However, any suitable configuration may be employed.

FIGS. 7, 8, and 10 are perspective views of the substrate 6 with a rectangular integrated support structure 14 as shown in FIG. 6. In one embodiment, the substrate upper surface 50 includes a protrusion 22 in the shape of a rectangular border as shown in FIG. 7. In another embodiment shown in FIG. 10, the substrate upper surface 50 includes a protrusion 22 used as the integrated support structure 14 in the shape of a partial rectangular border that surrounds a WLP40 of rectangular geometry.

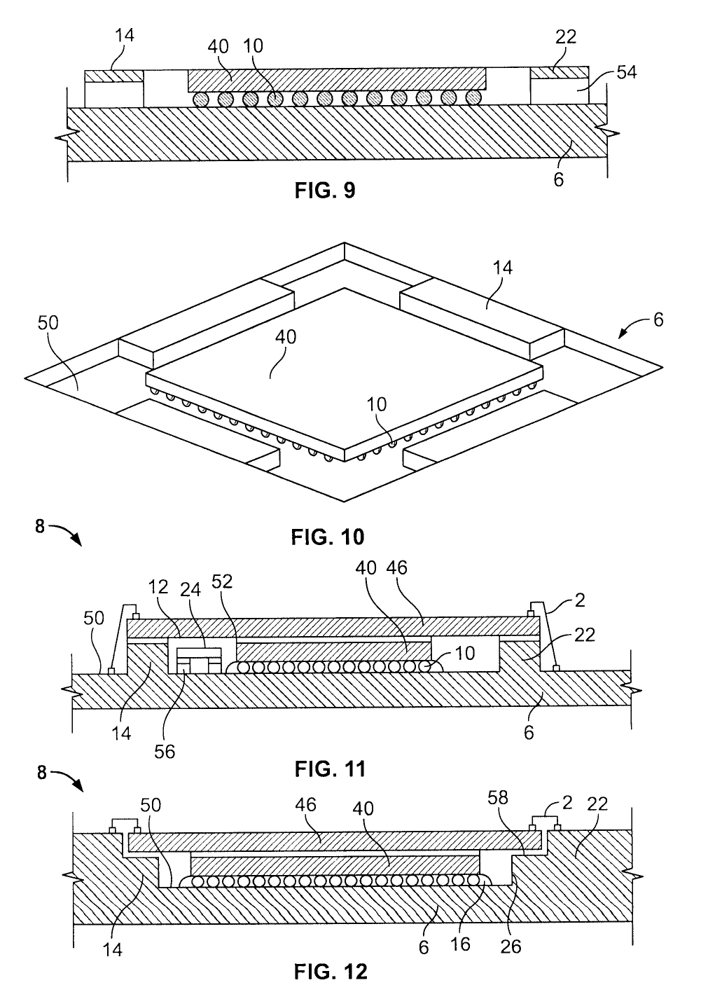

In yet another embodiment illustrated in FIGS. 8 and 9, the upper substrate surface 50 includes a protrusion 22 in the shape shown in FIG. 8 but with passages 54 to direct the flow of underfill 16 to the underfill area located between solder balls 10 of a WLP40 within the cavity created within the integrated support structure 14. One of ordinary skill in the art recognizes that the use of any shape of protrusion 22, with or without passages or openings, of strength sufficient to serve as a integrated support structure 14 is contemplated. FIG. 9 is a cross-sectional view of the integrated circuit package shown in FIG. 8 before underfill has been applied to the WLP.

In another embodiment shown in FIG. 11, passive electronic components 24, such as surface-mount capacitors, resistors, or other suitable elements, are placed between the integrated support structure 14 and the first circuit die 40. The components 24 are also located under the ledge 12. Illustratively, the passive electronic component 24 includes legs 56 attached to the substrate 8. FIG. 12 is a cross-sectional view of the integrated package shown in FIG. 6 where the integrated support structure 14 is made from a recess 26 shown in FIG. 10 in the upper substrate surface 50 to house the first circuit die 40. FIG. 12 also shows a situation where the recess 26 is made of two consecutive steps with an intermediate step 58 where the second circuit die 46 is placed for support by the integrated support structure 14. One of ordinary skill in the art recognizes that while one type of recess 26 is shown, it is disclosed is any combination of recess 26 created within the substrate 8 that allows for the support of the second circuit die 46 during wire bonding using a capillary machine.

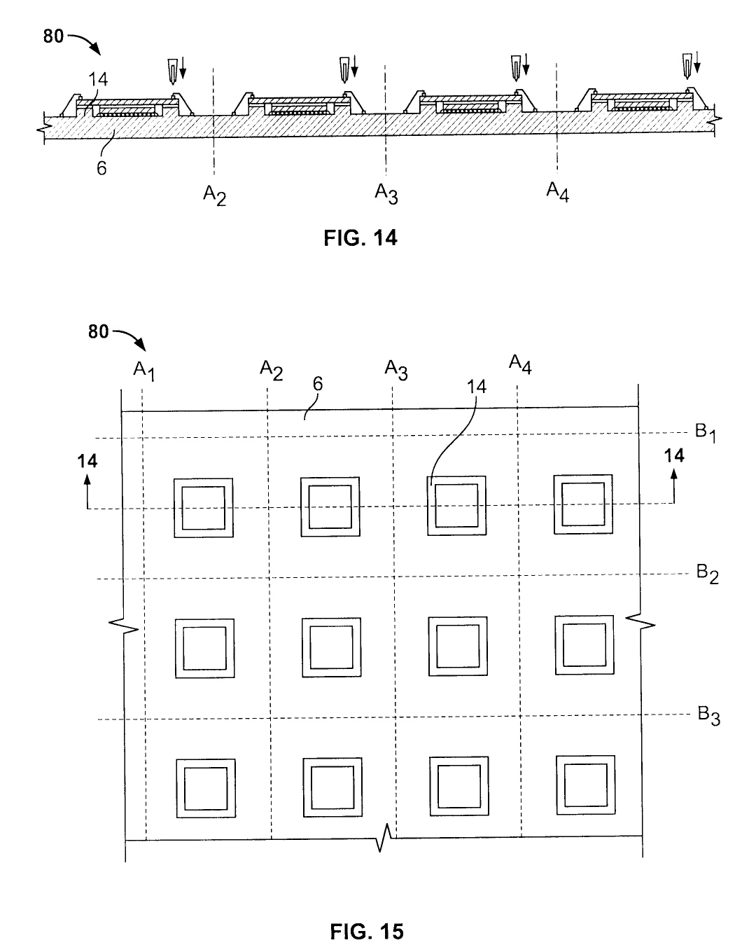

Also disclosed and illustrated in FIG. 14 is a product associated with producing an integrated circuit package strip 80 made of a plurality of integrated circuit packages 8 arranged on a plane along a strip where each of the plurality of integrated circuit packages 8 are made as described herebefore. FIG. 15 is a top view of the substrate of FIG. 14 where the different cut lines (A1 . . . A4 and B1 . . . B4) are shown. One of ordinary skill in the art recognizes that while a single integrated circuit package 8 can be produced, also contemplated is the production of arrays or strips of different sizes. In one preferred embodiment, strips of 5×19 or 6×23 individual integrated circuit packages 8 are contemplated and cut in a successive process into a series of individual integrated circuit packages 8.

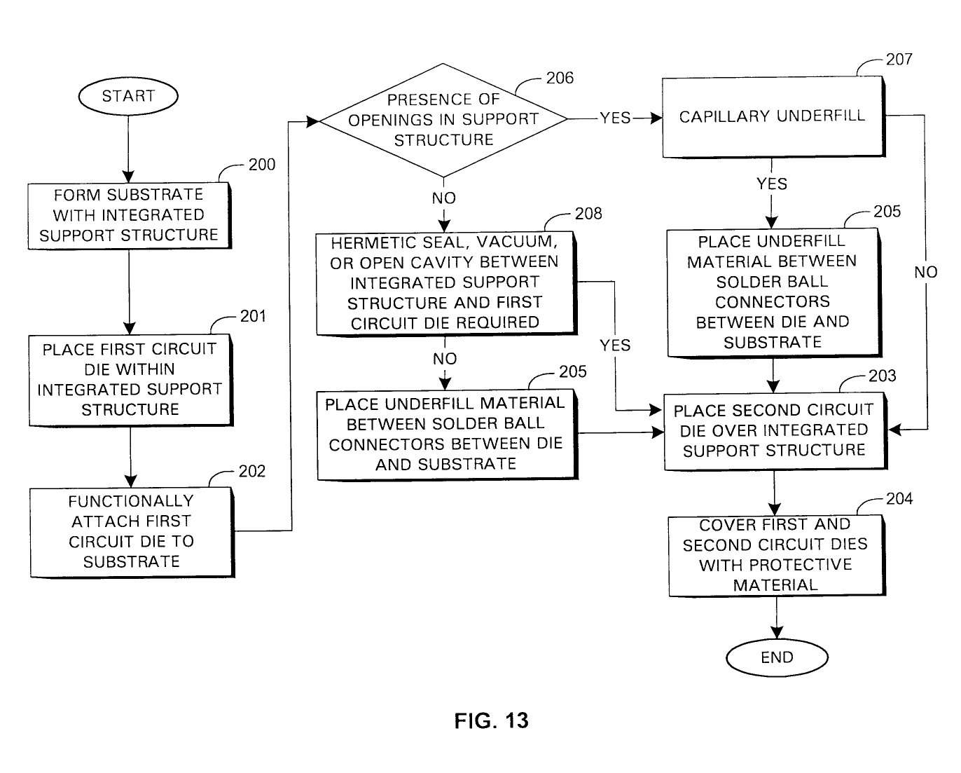

FIG. 13 is a flow chart of a method according to an embodiment of the present disclosure. The method of making an integrated circuit package 8 includes the successive steps of forming a substrate 6 to include an integrated support structure 14 in an upper substrate surface 50 (200), placing within the integrated support structure 14 of the upper substrate surface 50 a first circuit die 40 (201), functionally attaching the first circuit die 40 to the substrate (202), verifying the presence of openings in the support structure (206), and placing over the integrated support structure 14 of the upper substrate surface 50 a second circuit die 46 (203), and covering the first and second circuit dies 40, 46 with a protective material (204).

Also contemplated is the use of a method where the substrate 6 is formed by different processes, including but not limited to Lithographie Galvanoformung X-ray processes (LIGA processes), plastic forming, microelectromechanical systems processes (MEMS processes), bulk micromachining processes, surface micromachining processes, and other conventional integrated chip fabrication processes or standard organic and ceramic integrated chip laminated package fabrication processes combined with standard laser or mechanical milling process. In another contemplated embodiment, sacrificial material is used in the etching process stages. The first circuit die 40 is a flip-chip with solder ball connectors 10, the flip-chip solder balls 10 are attached to the upper substrate surface 50 by a reflow process, the protective material is an epoxy, and the second circuit die 46 is attached to the upper substrate surface 50 by wire bonding. In one alternate step of the above method, the integrated circuit package 8 is made by the process of further placing an underfill material by capillary action between the solder balls prior to reflow (205). This step is performed before the step of placing the second circuit die 203 if openings are not found or are absent in the support structure and a seal is not required 208.

As an intermediate step after a finding of the presence of openings 206, an underfill material 205 is placed between solder ball connectors between the die and substrate if a capillary underfill 207 is present, if no capillary underfill 207 is present, then the second circuit die 46 is placed over the integrated support structure 203 directly. Alternatively, if the presence of openings in the support structure 206 is not found, then if a hermetic seal, vacuum, or open cavity between the integrated support structure 14 and the first circuit die 40 is required 208, the second circuit die 46 is placed over the integrated support structure 203. If a hermetic seal, vacuum, or open cavity between the integrated support structure 14 and the first circuit die 40 is not required, then underfill material is placed between solder ball connectors between die and substrate 205 before the second circuit die 46 is placed over the integrated support structure 203.

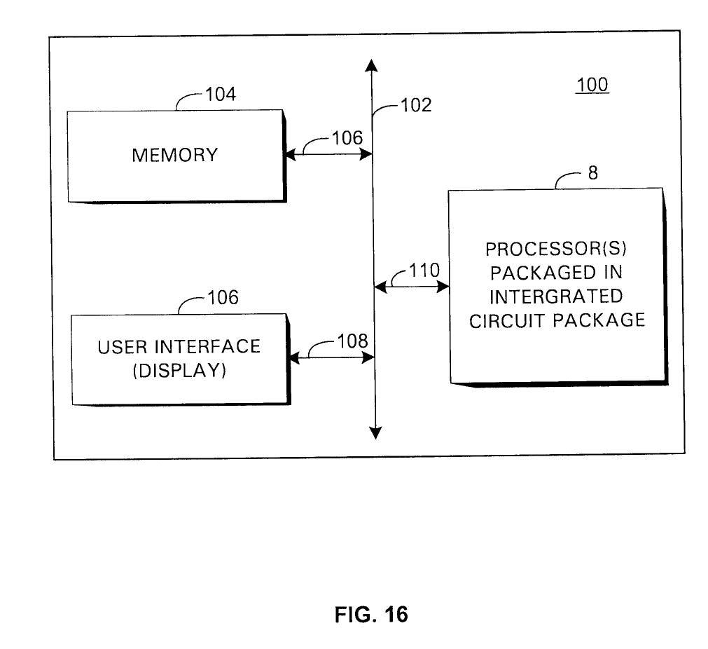

Referring now to FIG. 16, an exemplary device 100 embodying the present invention is illustrated. In particular, the device 100 comprises a processor packaged in an integrated circuit package 8 as described and contemplated in the present disclosure. The device 100 includes a storage or a memory component 106 coupled to a bus 102. In a preferred embodiment, the integrated circuit package 8 may comprise one or more processing devices, such as a microprocessor, graphics processor, microcontroller, digital signal processor, or combination thereof capable of executing the stored information from memory 106. Likewise, the storage may comprise one or more devices, such as volatile or nonvolatile memory including but not limited to random access memory (RAM) or read-only memory (ROM). Processor and storage arrangements of the types illustrated in FIG. 16 are well known to those having ordinary skill in the art.

In a presently preferred embodiment, the device exemplary of the invention may include one or more user input devices or user interfaces 106, such as, for example, a display, other input devices, or even a network interface (not shown) in communication with a processor. The user interface 106 may include any mechanism for providing user input to the processors packaged in an integrated circuit package 8. For example, the user interface 106 may include a keyboard, a mouse, a touch screen, or any other means whereby a user of the device 100 may provide input data to the processor packaged in an integrated circuit package 8. A display may include for example any conventional display mechanism such as a cathode ray tube (CRT), flat panel display, or any other display mechanism known to those having ordinary skill in the art. Other (optional) input devices may include various media drives (such as magnetic disk or optical disk drives) or any other source of input data. In one embodiment, the device 100 includes a user interface 106 and an integrated circuit package 8 operatively coupled to the user interface 106.

The invention as disclosed herein is not intended to be limited to the particular details of the package, strip, or method of manufacture described and depicted, and other modifications and applications may be contemplated. Any suitable devices, systems may employ integrated circuit packages such as but not limited to wireless hand held devices, laptops, desk top computers, printers, etc. Further changes may be made in the above-described method and device without departing from the true spirit and scope of the invention herein involved. It is intended, therefore, that the subject matter in the above disclosure should be interpreted as illustrative, not in a limiting sense.

What is claimed is:

1. An integrated circuit package, comprising:
a substrate with an upper substrate surface and a lower substrate surface;
a first circuit die supported by the substrate; and
a second circuit die positioned over the first circuit die and having a cantilevered portion that extends over an edge of the first circuit die,
wherein the substrate includes an integrated support structure.

2. The integrated circuit package of claim 1, wherein the integrated support structure is comprised of a protrusion of the upper substrate surface.

3. The integrated circuit package of claim 1, wherein a perimeter of the cantilevered portion comprises an edge and the integrated support structure is mechanically coupled only to a portion of the cantilevered portion adjacent to the outer edge.

4. The integrated circuit package of claim 1, wherein the integrated support structure defines at least one passage therethrough.

5. The integrated circuit package of claim 1, further comprising an adhesive between the first circuit die and the second circuit die.

6. The integrated circuit package of claim 5, further comprising a first bonding agent between the integrated support structure and the cantilevered portion.

7. The integrated circuit package of claim 1, comprising a passive electronic component located under the cantilevered portion and between the integrated support structure and the first circuit die.

8. The integrated circuit package of claim 1, wherein the first circuit die is a packaged integrated flip-chip ball grid array.

9. The integrated circuit package of claim 2, wherein the protrusion of the upper substrate surface surrounds the first circuit die.

10. The integrated circuit package of claim 9, wherein the protrusion comprises a series of passages to allow for an underflow material to pass through the protrusion.

11. The integrated circuit package of claim 2, wherein the protrusion of the upper substrate surface partially surrounds the first circuit die.

12. The integrated circuit package of claim 1, wherein the substrate and the integrated support structure are made of a material from the group consisting of silicon, metal, plastic, ceramic, semiconductive material, conductive material, or insulating material.

13. The integrated circuit package of claim 1, wherein the integrated support structure is a surface that surrounds a recess in the upper substrate surface to house the first circuit die.

14. An integrated circuit package strip, comprising:
a plurality of integrated circuit packages arranged on a plane in a strip where each of the plurality of integrated circuit package comprise a substrate with an upper substrate surface and a lower substrate surface, a first circuit die supported by the substrate, and a second circuit die positioned over the first circuit die and having a ledge that extends over an edge of the first circuit die, and wherein the substrate includes an integrated support structure as support for the ledge of the second die.

15. The integrated circuit package strip of claim 14, wherein the integrated support structure of each of the plurality of integrated circuit packages is comprised of a protrusion of the upper substrate surface.

16. The integrated circuit package strip of claim 14, wherein a perimeter of the ledge of each of the plurality of integrated circuit packages comprises an edge and the integrated support structure of each of the plurality of integrated circuit packages is mechanically coupled only to a portion of the ledge adjacent to the outer edge of each of the plurality of integrated circuit packages.

17. The integrated circuit package strip of claim 14, wherein the integrated support structure of each of the plurality of integrated circuit packages defines at least one passage therethrough.

18. The integrated circuit package strip of claim 14, further comprising an adhesive between the first circuit die of each of the plurality of integrated circuit packages and the second circuit die of the same integrated circuit packages.

19. The integrated circuit package strip of claim 18, further comprising a first bonding agent between the integrated support structure and the ledge.

20. The integrated circuit package strip of claim 15, wherein the protrusion of the upper substrate surface of each of the plurality of integrated circuit packages surrounds the first circuit die for each of the plurality of integrated circuit packages.

21. The integrated circuit package strip of claim 20, wherein the protrusion of each of the plurality of integrated circuit packages comprises a series of passages to allow for an underfill material to pass through the protrusion.

22. The integrated circuit package strip of claim 15, wherein the protrusion of the upper substrate surface of each of the plurality of integrated circuit packages partially surrounds the first circuit die of each of the plurality of integrated circuit packages.

23. The integrated circuit package strip of claim 14, wherein the substrate and the integrated support structure is made of a material from the group consisting of silicon, metal, plastic, ceramic, semiconductive material, conductive material, or insulating material.

24. A method of making an integrated circuit package, comprising the steps of forming a substrate to include an integrated support structure in an upper substrate surface, placing within the integrated support structure of the upper substrate surface a first circuit die, functionally attaching the first circuit die to the substrate, placing over the integrated support structure of the upper substrate surface a second circuit die.

25. The method of making an integrated circuit package of claim 24, wherein the substrate is formed by a process selected from the group consisting of Lithographie Galvanoformung X-ray (LIGA), plastic forming, microelectromechanical systems (MEMS), bulk micromachining, surface micromachining, conventional fabrication, or standard organic and ceramic integrated chip laminated package fabrication combined with standard laser or mechanical milling process.

26. The method of making an integrated circuit package of claim 25, further comprising placing an underfill material by capillary action between the solder balls.
